(19) United States
(12) Patent Application Publication
(10) Pub. No.: US 2010/0071765 A1
(43) Pub. Date: Mar. 25, 2010

(54) METHOD FOR FABRICATING A SOLAR CELL USING A DIRECT-PATTERN PIN-HOLE-FREE MASKING LAYER

(76) Inventors: Peter Cousins, Menlo Park, CA (US); Hsin-Chiao Luan, Palo Alto, CA (US)

Correspondence Address: SunPower/ BSTZ;Blakely Sokoloff Taylor & Zafman LLP, 1279 OAKMEAD PARKWAY, SUNNYVALE, CA, 94085-4040, US

(21) Appl. No.: 12/233,819

(22) Filed: Sep. 19, 2008

(51) Int. Cl. H01L 31/00; H01L 21/00

(52) U.S. Cl. 136/258; 438/98; 257/E31.001; 257/E21.001

(57) ABSTRACT

A method for fabricating a solar cell is described. The method includes first providing a substrate having a dielectric layer disposed thereon. A pin-hole-free masking layer is then formed above the dielectric layer. Finally, without the use of a mask, the pin-hole-free masking layer is patterned to form a patterned pin-hole-free masking layer.

This invention was made with Government support under ZAX-4-33628-05 awarded by the United States Department of Energy under the photovoltaic (PV) Manufacturing Research and Development (R&D) Program, which is administered by the National Renewable Energy Laboratory. The Government has certain rights in the invention.

### TECHNICAL FIELD

Embodiments of the present invention are in the field of solar cell fabrication and, in particular, direct-pattern pin-hole-free masks for solar cell fabrication.

### BACKGROUND

Photovoltaic cells, commonly known as solar cells, are well known devices for direct conversion of solar radiation into electrical energy. Generally, solar cells are fabricated on a semiconductor wafer or substrate using semiconductor processing techniques to form a p-n junction near a surface of the substrate. Solar radiation impinging on the surface of the substrate creates electron and hole pairs in the bulk of the substrate, which migrate to p-doped and n-doped regions in the substrate, thereby generating a voltage differential between the doped regions. The doped regions are coupled to metal contacts on the solar cell to direct an electrical current from the cell to an external circuit coupled thereto.

Typically, metal contacts are formed by first patterning a dielectric layer or stack formed at the back-side of a photovoltaic substrate. For example, a screen print process is used to form a pattern of ink on the dielectric layer. The dielectric layer is then patterned using the pattern of ink as a mask during an etch process. However, global (as opposed to regional) etch processes are typically used. Accordingly, any pin-holes that exist in the pattern of ink are also patterned into the dielectric layer to form pin-holes in the dielectric layer. A metal layer used to form metal contacts in the patterned dielectric layer may undesirably fill the pin-holes formed in the patterned dielectric layer, potentially causing shorts or other defects.

### BRIEF DESCRIPTION OF THE DRAWINGS

FIG. 1 depicts a Flowchart representing a series of operations in a method for fabricating a solar cell, in accordance with an embodiment of the present invention.

FIG. 2A illustrates a cross-sectional view of a substrate having a dielectric layer disposed thereon, corresponding to operation 102 from the Flowchart of FIG. 1, in accordance with an embodiment of the present invention.

FIG. 2B illustrates a cross-sectional view of a substrate having a pin-hole-free masking layer formed thereon, corresponding to operation 104 from the Flowchart of FIG. 1, in accordance with an embodiment of the present invention.

FIG. 2C illustrates a cross-sectional view of a substrate having a patterned pin-hole-free masking layer formed thereon, corresponding to operation 106 from the Flowchart of FIG. 1, in accordance with an embodiment of the present invention.

FIG. 2D illustrates a cross-sectional view of a substrate having a patterned dielectric layer and a patterned pin-hole-free masking layer formed thereon, corresponding to operation 108 from the Flowchart of FIG. 1, in accordance with an embodiment of the present invention.

FIG. 2E illustrates a cross-sectional view of a substrate having a patterned dielectric layer formed thereon, wherein a patterned pin-hole-free masking layer has been removed, corresponding to operation 110 from the Flowchart of FIG. 1, in accordance with an embodiment of the present invention.

FIG. 2F illustrates a cross-sectional view of a substrate having a plurality of metal contacts formed thereon, corresponding to operation 112 from the Flowchart of FIG. 1, in accordance with an embodiment of the present invention.

### DETAILED DESCRIPTION

Methods to fabricate a solar cell are described herein. In the following description, numerous specific details are set forth, such as specific chemical compatibilities, in order to provide a thorough understanding of the present invention. It will be apparent to one skilled in the art that embodiments of the present invention may be practiced without these specific details. In other instances, well-known processing steps, such as metal deposition steps, are not described in detail in order to not unnecessarily obscure embodiments of the present invention. Furthermore, it is to be understood that the various embodiments shown in the Figures are illustrative representations and are not necessarily drawn to scale.

Disclosed herein is a method to fabricate a solar cell. A substrate may first be provided having a dielectric layer disposed thereon. In one embodiment, a pin-hole-free masking layer is then formed above the dielectric layer. Without the use of a mask, the pin-hole-free masking layer may then be patterned to form a patterned pin-hole-free masking layer. In one embodiment, the dielectric layer protects the substrate during the patterning. In one embodiment, using the patterned pin-hole-free masking layer as a mask, the dielectric layer is then etched to form a patterned dielectric layer and to expose a portion of the substrate. The patterned pin-hole-free masking layer is then removed to expose the patterned dielectric stack and a plurality of metal contacts is formed in the patterned dielectric stack.

The utilization of a direct-pattern pin-hole-free masking layer may substantially eliminate the formation of pin-holes in a dielectric layer or stack used for forming a plurality of metal contacts on the back-side of a solar cell. In accordance with an embodiment of the present invention, a pin-hole-free masking layer is used in place of an ink layer in a patterning process utilized to ultimately form a plurality of metal contacts for a solar cell. The pin-hole-free masking layer may be patterned by a direct pattern, as opposed to a masked, patterning process. In one embodiment, the direct-pattern pin-hole-free masking layer is patterned by using a laser ablation technique. In another embodiment, the direct-pattern pin-hole-free masking layer is patterned by using a spot etching technique.

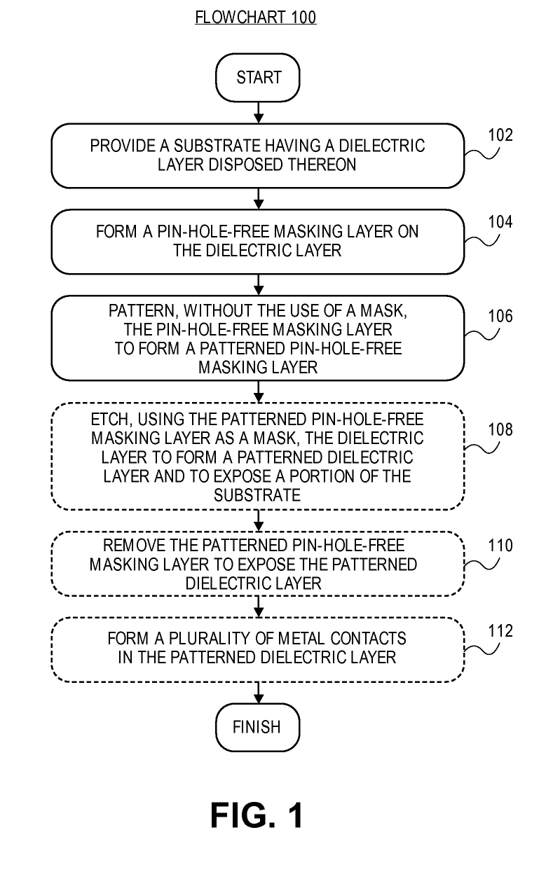

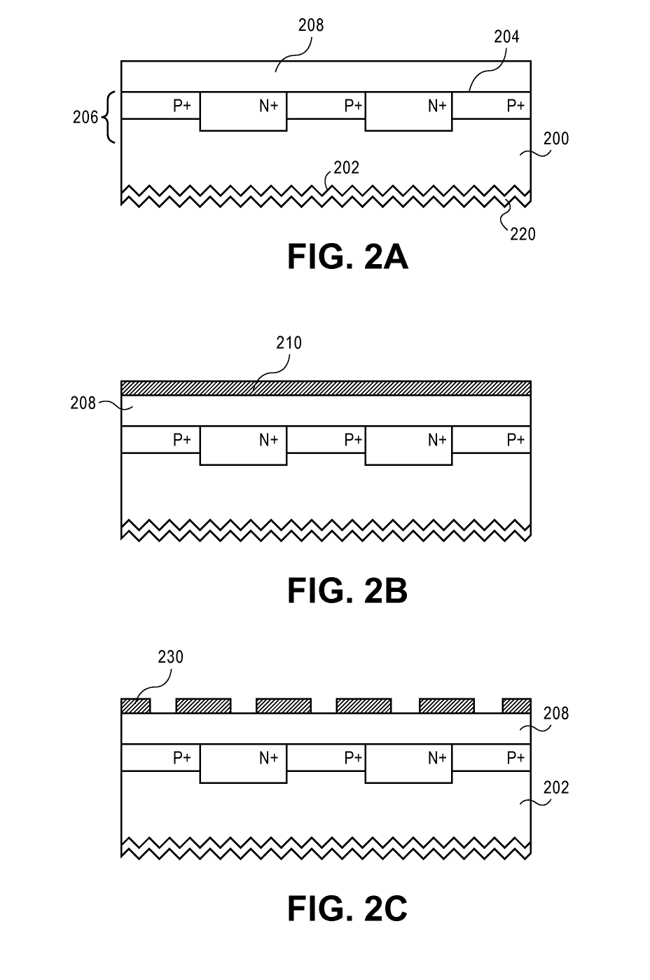

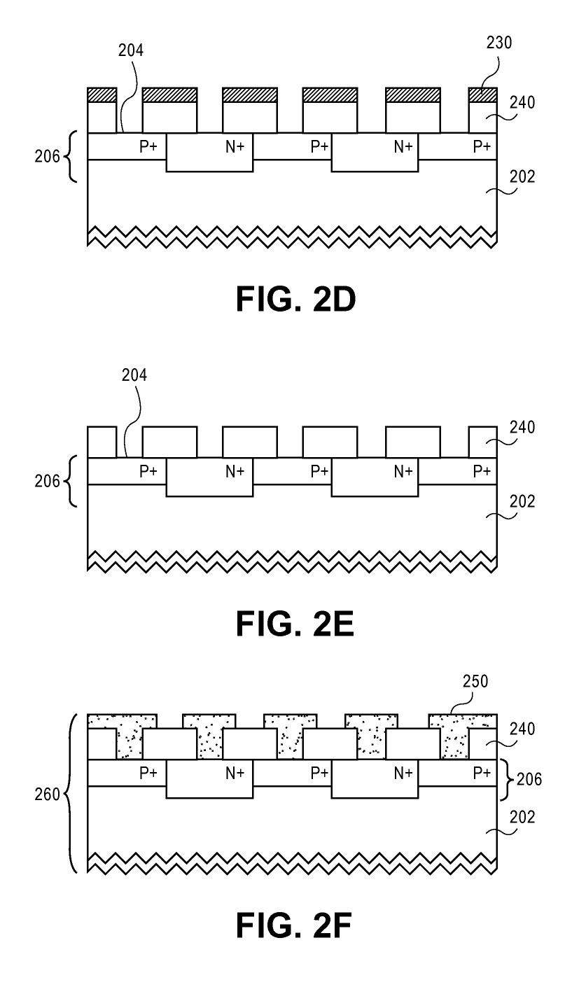

A direct-pattern pin-hole-free masking layer may be utilized in the fabrication of a solar cell. FIG. 1 depicts a Flowchart 100 representing a series of operations in a method for fabricating a solar cell, in accordance with an embodiment of the present invention. FIGS. 2A-2F illustrate cross-sectional views representing operations in the fabrication of a solar cell, corresponding to the operations of Flowchart 100, in accordance with an embodiment of the present invention.

FIG. 2A illustrates a cross-sectional view of a substrate having a dielectric layer disposed thereon, corresponding to operation 102 from Flowchart 100, in accordance with an embodiment of the present invention. Referring to operation 102 of Flowchart 100 and corresponding FIG. 2A, a substrate is provided having a dielectric layer disposed thereon.

Referring to FIG. 2A, a substrate 200 has a light-receiving surface 202 and a back surface 204. In an embodiment, light-receiving surface 202 is textured, as depicted in FIG. 2A, to mitigate undesirable reflection during solar radiation collection efficiency. In one embodiment, an anti-reflective coating layer 220 is formed on and conformal with light-receiving surface 202 of substrate 200. A plurality of active regions 206 is formed at back surface 204 of substrate 200. In accordance with an embodiment of the present invention, the plurality of active regions 206 includes alternating N+ and P+ regions, as depicted in FIG. 2A. In one embodiment, substrate 200 is composed of crystalline silicon, the N+ regions include phosphorous dopant impurity atoms and the P+ regions include boron dopant impurity atoms. A dielectric layer 208 is disposed on back surface 204 of substrate 200. In one embodiment, dielectric layer 208 is composed of a material such as, but not limited to, silicon dioxide. In another embodiment, dielectric layer 208 is a stack of dielectric layers, e.g., dielectric layer 208 includes a layer of silicon dioxide disposed on substrate 200 and a layer of silicon nitride disposed on the layer of silicon dioxide.

FIG. 2B illustrates a cross-sectional view of a substrate having a pin-hole-free masking layer formed thereon, corresponding to operation 104 from Flowchart 100, in accordance with an embodiment of the present invention. Referring to operation 104 of Flowchart 100 and corresponding FIG. 2B, a pin-hole-free masking layer is formed above the dielectric layer.

Referring to FIG. 2B, a pin-hole-free masking layer 210 is formed on the surface of dielectric layer 208. Pin-hole-free masking layer 210 may be formed by a technique suitable to provide conformal coverage of dielectric layer 208 without the formation of pin-holes. In accordance with an embodiment of the present invention, forming pin-hole-free masking layer 210 includes using a chemical vapor deposition technique. In one embodiment, using the chemical vapor deposition technique includes depositing a material such as, but not limited to, amorphous silicon, amorphous carbon, or polyimide. In a specific embodiment, pin-hole-free masking layer 210 is composed of amorphous silicon and is formed by chemical vapor deposition using a gas such as, but not limited to, silane (SiH₄) or disilane (Si₂H₆). In another specific embodiment, pin-hole-free masking layer 210 is composed of amorphous carbon and is formed by chemical vapor deposition using a gas such as, but not limited to, methane (CH₄), ethane (C₂H₆), propane (C₃H₈), ethylene (C₂H₄) or propylene (C₃H₆). For efficiency of fabrication, pin-hole-free masking layer 210 may be deposited in the same process operation as the deposition of dielectric layer 208. For example, in one embodiment, dielectric layer 208 is a stack of dielectric layers including a layer of silicon nitride and pin-hole-free masking layer 210 is deposited in the same process chamber and in the same process step as the silicon nitride layer by sequencing the deposition gases used in a chemical vapor deposition process. In another embodiment, forming pin-hole-free masking layer 210 includes forming an amorphous silicon layer on a silicon dioxide dielectric layer 208 in separate process operations.

FIG. 2C illustrates a cross-sectional view of a substrate having a patterned pin-hole-free masking layer formed thereon, corresponding to operation 106 from Flowchart 100, in accordance with an embodiment of the present invention. Referring to operation 106 of Flowchart 100 and corresponding FIG. 2C, a pin-hole-free masking layer is patterned, without the use of a mask, to form a patterned pin-hole-free masking layer.

Referring to FIG. 2C, pin-hole-free masking layer 210 on dielectric layer 208 is patterned to form patterned pin-hole-free masking layer 230. In an embodiment, the pattern of patterned pin-hole-free masking layer 230 determines the location where a plurality of contact openings will subsequently be formed in dielectric layer 208. Pin-hole-free masking layer 210 may be patterned to form patterned pin-hole-free masking layer 230 by a technique suitable to selectively pattern pin-hole-free masking layer 210 without significantly impacting dielectric layer 208. In accordance with an embodiment of the present invention, the patterning of pin-hole-free masking layer 210 to form patterned pin-hole-free masking layer 230 includes using a laser ablation technique with a laser. In one embodiment, using the laser ablation technique includes selecting the wavelength of the laser such that pin-hole-free masking layer 210 has a faster ablation rate than dielectric layer 208. In a specific embodiment, dielectric layer 208 protects substrate 200 during the laser ablation because the band-gap of dielectric layer 208 is greater than the band-gap of substrate 200 and, in the absence of dielectric layer 208, substrate 200 would otherwise be undesirably impacted by the laser ablation process used to pattern pin-hole-free masking layer 210.

In accordance with another embodiment of the present invention, the patterning of pin-hole-free masking layer 210 to form patterned pin-hole-free masking layer 230 includes using a spot etching technique. In one embodiment, using the spot etching technique includes selecting a wet etchant such that pin-hole-free masking layer 210 has a faster etch rate than dielectric layer 208. In a specific embodiment, selecting the wet etchant includes using an aqueous solution of potassium hydroxide. In a particular embodiment, dielectric layer 208 protects substrate 200 during the spot etching because the etch rate of dielectric layer 208 is considerably slower than the etch rate of substrate 200 and, in the absence of dielectric layer 208, substrate 200 would otherwise be undesirably impacted by the spot etching used to pattern pin-hole-free masking layer 210. It is noted that a direct spot etching of dielectric layer 208 may be ineffective due to a considerable thickness of dielectric layer 208 relative to the thickness of pin-hole-free masking layer 210. Thus, in accordance with an embodiment of the present invention, it is beneficial to use a direct-pattern pin-hole-free masking layer to pattern a dielectric layer when fabricating a plurality of metal contacts for a solar cell. In one embodiment, dielectric layer 208 has a thickness approximately in the range of 100-500 nanometers and pin-hole-free masking layer 210 has a thickness approximately in the range of 1-100 nanometers. In an embodiment, the patterning of pin-hole-free masking layer 210 includes preserving the entire dielectric layer 210 during the patterning process.

Thus, as described in association with FIGS. 2A-2C, a pin-hole-free masking layer can be patterned, without the use of a mask, to form a patterned pin-hole-free masking layer. Following formation of the patterned pin-hole-free masking layer, metal contacts for a back-contacted solar cell may be fabricated, as described in association with FIGS. 2D-2F.

FIG. 2D illustrates a cross-sectional view of a substrate having a patterned dielectric layer and a patterned pin-hole-free masking layer formed thereon, corresponding to operation 108 from Flowchart 100, in accordance with an embodiment of the present invention. Referring to operation 108 of Flowchart 100 and corresponding FIG. 2D, a dielectric layer is etched, using a patterned pin-hole-free masking layer as a mask, to form a patterned dielectric layer and to expose a portion of a substrate.

Referring to FIG. 2D, a plurality of contact openings is formed in dielectric layer 208 to form patterned dielectric layer 240 by using patterned pin-hole-free masking layer 230 as a mask. Dielectric layer 208 may be patterned to form patterned dielectric layer 240 by a technique suitable to selectively transfer the pattern from patterned pin-hole-free masking layer 230 without significantly impacting (e.g. etching) back surface 204 of substrate 200, i.e., without degrading the effectiveness of the plurality of active regions 206. In accordance with an embodiment of the present invention, dielectric layer 208 is patterned to form patterned dielectric layer 240 by etching dielectric layer 208 using a global buffered oxide etchant, e.g., by submersing substrate 200 in a buffered oxide etchant. In one embodiment, the buffered oxide etchant is composed of an aqueous solution that includes hydrofluoric acid (HF) and ammonium fluoride (NH₄F). In a specific embodiment, the HF:NH₄F ratio is approximately in the range of 1:4-1:10 and the buffered oxide etchant is applied to dielectric layer 208 for a duration approximately in the range of 3-10 minutes at a temperature approximately in the range of 30-40 degrees Celsius.

FIG. 2E illustrates a cross-sectional view of a substrate having a patterned dielectric layer formed thereon, wherein a patterned pin-hole-free masking layer has been removed, corresponding to operation 110 from Flowchart 100, in accordance with an embodiment of the present invention. Referring to operation 110 of Flowchart 100 and corresponding FIG. 2E, a patterned pin-hole-free masking layer is removed to expose a patterned dielectric layer.

Referring to FIG. 2E, patterned pin-hole-free masking layer 210 is removed selectively to provide patterned dielectric layer 240 having a plurality of openings formed therein. In accordance with an embodiment of the present invention, patterned pin-hole-free masking layer 210 is removed selectively by a technique suitable to maintain the pattern integrity of patterned dielectric layer 240 without significantly impacting (e.g. etching) back surface 204 of substrate 200, i.e., without degrading the effectiveness of the plurality of active regions 206. In one embodiment, the removing of patterned pin-hole-free masking layer 230 includes using an aqueous solution of potassium hydroxide.

FIG. 2F illustrates a cross-sectional view of a substrate having a plurality of metal contacts formed thereon, corresponding to operation 110 from Flowchart 100, in accordance with an embodiment of the present invention. Referring to operation 112 of Flowchart 100 and corresponding FIG. 2F, a plurality of metal contacts is formed in a patterned dielectric layer.

Referring to FIG. 2F, a plurality of metal contacts 250 is formed by depositing and patterning a metal-containing material within patterned dielectric layer 240 and on the plurality of active regions 206. In one embodiment, the metal-containing material used to form the plurality of metal contacts 250 is composed of a metal such as, but not limited to, aluminum, silver, palladium or alloys thereof. In accordance with an embodiment of the present invention, a back side contact solar cell 260 is thus formed. Back side contact solar cells are also disclosed in U.S. Pat. Nos. 5,053,083 and 4,927,770, the entire contents of which are hereby incorporated by reference herein.

Thus, a method for fabricating a solar cell has been disclosed. In accordance with an embodiment of the present invention, a substrate is provided having a dielectric layer disposed thereon. A pin-hole-free masking layer is formed above the dielectric layer. Without the use of a mask, the pin-hole-free masking layer is patterned to form a patterned pin-hole-free masking layer. In one embodiment, the dielectric layer protects the substrate during the patterning.

What is claimed is:

1. A method for fabricating a solar cell, comprising:
providing a substrate having a dielectric layer disposed thereon;
forming a pin-hole-free masking layer above the dielectric layer;
patterning, without the use of a mask, the pin-hole-free masking layer to form a patterned pin-hole-free masking layer, wherein the dielectric layer protects the substrate during the patterning.

2. The method of claim 1, wherein patterning the pin-hole-free masking layer comprises using a laser ablation technique with a laser having a wavelength.

3. The method of claim 2, wherein using the laser ablation technique comprises selecting the wavelength of the laser such that the pin-hole-free masking layer has a faster ablation rate than the dielectric layer.

4. The method of claim 1, wherein patterning the pin-hole-free masking layer comprises using a spot etching technique with a wet etchant.

5. The method of claim 4, wherein using the spot etching technique comprises selecting the wet etchant such that the pin-hole-free masking layer has a faster etch rate than the dielectric layer.

6. The method of claim 5, wherein selecting the wet etchant comprises using an aqueous solution of potassium hydroxide.

7. The method of claim 1, wherein forming the pin-hole-free masking layer comprises using a chemical vapor deposition technique.

8. The method of claim 7, wherein using the chemical vapor deposition technique comprises depositing a material selected from the group consisting of amorphous silicon, amorphous carbon, and polyimide.

9. The method of claim 1, wherein providing a substrate having a dielectric layer comprises providing a crystalline silicon substrate having a silicon dioxide layer disposed thereon, and wherein forming the pin-hole-free masking layer comprises forming an amorphous silicon layer above the silicon dioxide layer.

10. The method of claim 1, wherein patterning the pin-hole-free masking layer comprises preserving the entire dielectric layer.

11. A method for fabricating a solar cell, comprising:
providing a substrate having a dielectric stack disposed thereon;
forming a pin-hole-free masking layer on the dielectric stack;
patterning, without the use of a mask, the pin-hole-free masking layer to form a patterned pin-hole-free masking layer, wherein the dielectric stack protects the substrate during the patterning;
etching, using the patterned pin-hole-free masking layer as a mask, the dielectric stack to form a patterned dielectric stack and to expose a portion of the substrate;
removing the patterned pin-hole-free masking layer to expose the patterned dielectric stack; and
forming a plurality of metal contacts in the patterned dielectric stack.

12. The method of claim 11, wherein etching the dielectric stack comprises using a global buffered oxide etchant.

13. The method of claim 11, wherein removing the patterned pin-hole-free masking layer comprises using an aqueous solution of potassium hydroxide.

14. The method of claim 11, wherein patterning the pin-hole-free masking layer comprises using a laser ablation technique with a laser having a wavelength, and wherein using the laser ablation technique comprises selecting the wavelength of the laser such that the pin-hole-free masking layer has a faster ablation rate than the dielectric stack.

15. The method of claim 11, wherein patterning the pin-hole-free masking layer comprises using a spot etching technique with a wet etchant, and wherein using the spot etching technique comprises selecting the wet etchant such that the pin-hole-free masking layer has a faster etch rate than the dielectric stack.

16. The method of claim 15, wherein selecting the wet etchant comprises using an aqueous solution of potassium hydroxide.

17. The method of claim 11, wherein forming the pin-hole-free masking layer comprises using a chemical vapor deposition technique.

18. The method of claim 17, wherein using the chemical vapor deposition technique comprises depositing a material selected from the group consisting of amorphous silicon, amorphous carbon, and polyimide.

19. The method of claim 11, wherein providing a substrate having a dielectric stack comprises providing a crystalline silicon substrate having a silicon dioxide layer disposed on the substrate and a silicon nitride layer disposed on the silicon dioxide layer, and wherein forming the pin-hole-free masking layer comprises forming an amorphous silicon layer on the silicon nitride layer.

20. The method of claim 11, wherein patterning the pin-hole-free masking layer comprises preserving the entire dielectric stack.

21. A solar cell, comprising:
a substrate having a patterned dielectric layer disposed thereon; and
a patterned pin-hole-free masking layer disposed above the patterned dielectric layer, wherein the patterned dielectric layer and the patterned pin-hole-free masking layer have approximately the same pattern.

22. The solar cell of claim 21, wherein the patterned pin-hole-free masking layer comprises a material selected from the group consisting of amorphous silicon, amorphous carbon, and polyimide.

23. The solar cell claim 21, wherein the substrate comprises crystalline silicon, wherein the patterned dielectric layer comprises silicon dioxide, and wherein the patterned pin-hole-free masking layer comprises amorphous silicon.
